(19) United States
(12) Patent Application Publication
(10) Pub. No.: US 2025/0351683 A1
(43) Pub. Date: Nov. 13, 2025

(54) DISPLAY DEVICE

(71) Applicant: Samsung Display Co., LTD., Yongin-si (KR)

(72) Inventors: Hwangsup SHIN, Yongin-si (KR); Changha KWak, Yongin-si (KR); Eungtaek KIM, Yongin-si (KR); Jonghyeon KIM, Yongin-si (KR); Heeyeon KIM, Yongin-si (KR); Jeonga RYU, Yongin-si (KR); Kwanyong PAK, Yongin-si (KR); Nalae LEE, Yongin-si (KR); Jinho JEONG, Yongin-si (KR); Joohyeon JO, Yongin-si (KR); Kyungmi CHOI, Yongin-si (KR); Jungmi CHOI, Yongin-si (KR); Hongjun CHOI, Yongin-si (KR)

(21) Appl. No.: 19/031,729

(22) Filed: Jan. 18, 2025

(30) Foreign Application Priority Data
May 10, 2024 (KR) 10-2024-0062186

(51) Int. Cl. H10K 59/124; H10K 59/80

(52) U.S. Cl. CPC H10K 59/124; H10K 59/873

(57) ABSTRACT

A display device includes a substrate, a first buffer layer disposed on the substrate, a thin film transistor including a semiconductor layer disposed on the first buffer layer and a gate electrode insulated from the first semiconductor layer, and a first inorganic insulating layer disposed between the semiconductor layer and the gate electrode. A concentration of H in the first inorganic insulating layer is about 7.55×10²⁰ atoms per cubic centimeter (atom/cm³) or less, and a content of a compound including a nitrogen-hydrogen (N—H) bond in the first buffer layer is about 0.1% or less based on a total weight of the buffer layer.

This application claims priority to Korean Patent Application No. 10-2024-0062186, filed on May 10, 2024, and all the benefits accruing therefrom under 35 U.S.C. § 119, the content of which in its entirety is herein incorporated by reference.

### BACKGROUND

### 1. Field

Embodiments relate to display devices.

### 2. Description of the Related Art

Display devices visually display data. The display devices may provide images by light-emitting diodes. The display devices have a variety of uses, and a variety of designs to improve the quality of display devices have been attempted.

### SUMMARY

Embodiments include display devices.

Additional features will be set forth in part in the description which follows and, in part, will be apparent from the description, or may be learned by practice of the presented embodiments of the disclosure.

In an embodiment of the disclosure, a display device includes a substrate, a first buffer layer disposed on the substrate, a thin film transistor including a semiconductor layer disposed on the first buffer layer and a gate electrode insulated from the first semiconductor layer, and a first inorganic insulating layer disposed between the first semiconductor layer and the gate electrode, where a concentration of H in the first inorganic insulating layer is about 7.55×10²⁰ atoms per cubic centimeter (atom/cm³) or less, and a content of a compound including or consisting of a nitrogen-hydrogen (N—H) bond in the first buffer layer is about 0.1% or less based on a total weight of the buffer layer.

In an embodiment, the concentration of H in the first buffer layer may be 8.5×10²⁰ atom/cm³ or less.

In an embodiment, the first buffer layer may include silicon oxide (SiOₓ).

In an embodiment, the display device may further include a second buffer layer disposed below the first buffer layer.

In an embodiment, the second buffer layer may include SiNₓ.

In an embodiment, the first inorganic insulating layer may include SiOₓ.

In an embodiment, the content of fluorine in an interface between the buffer layer and the semiconductor layer may be six times or more of a minimum value of the content of fluorine in a lower portion of the buffer layer.

In an embodiment, the semiconductor layer may include silicon semiconductor material.

In an embodiment, the display device may further include a metal layer disposed on the substrate.

In an embodiment, the thin film transistor may include a driving thin film transistor.

In an embodiment, the substrate may include a glass material.

In an embodiment, the substrate may include an inorganic layer disposed between plastic substrates next to each other.

In an embodiment, the plastic substrates may each include polyimide.

In an embodiment, the inorganic layer may include SiOₓ.

In an embodiment, the display device may further include an organic insulating layer disposed on the first inorganic insulating layer.

In an embodiment, the display device may further include an organic light-emitting diode disposed on the organic insulating layer.

In an embodiment, the organic light-emitting diode may include a pixel electrode, an emission layer, and a counter electrode.

In an embodiment, the display device may further include an encapsulation layer disposed on the organic light-emitting diode.

In an embodiment, the encapsulation layer may include a first inorganic encapsulation layer, an organic encapsulation layer, and a second inorganic encapsulation layer.

In an embodiment, the display device may further include a storage capacitor disposed on the thin film transistor.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic perspective view of an embodiment of a display device;

FIG. 2 is a schematic plan view of an embodiment of a display device;

FIGS. 3 and 4 are equivalent circuit diagrams of an embodiment of a pixel in a display device;

FIG. 5 is a schematic cross-sectional view of a pixel taken along line I-I′ of FIG. 1; and

FIG. 6 is a graph schematically showing the content of fluorine in a first buffer layer, a semiconductor layer, and a first inorganic insulating layer.

### DETAILED DESCRIPTION

Reference will now be made in detail to embodiments, illustrative embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the illustrated embodiments, and particular embodiments will be illustrated in the drawings and described in the detailed description section. The effect and features of the illustrated embodiments, and a method to achieve the same, will be clearer referring to the detailed descriptions below with the drawings. However, the illustrated embodiments may be implemented in various forms, not by being limited to the embodiments presented below.

Hereinafter, embodiments will be described in detail with reference to the accompanying drawings, and in the description with reference to the drawings, the same or corresponding constituents are indicated by the same reference numerals and redundant descriptions thereof are omitted.

In the following embodiment, it will be understood that although the terms first, second, etc. may be used herein to describe various elements, these elements should not be limited by these terms. These elements are only used to distinguish one element from another.

In the following embodiment, as used herein, the singular forms “a,” “an,” and “the” are intended to include the plural forms as well, unless the context clearly indicates otherwise.

In the following embodiment, it will be further understood that the terms “comprises” and/or “comprising” used herein specify the presence of stated features or elements, but do not preclude the presence or addition of one or more other features or components.

In the following embodiment, it will be understood that when an element, such as a layer, a film, a region, or a plate, is referred to as being “on” another element, the element may be directly on the other element or intervening elements may be thereon.

Sizes of elements in the drawings may be exaggerated for convenience of explanation. For example, since sizes and thicknesses of elements in the drawings are arbitrarily illustrated for convenience of explanation, the following the disclosure is not limited thereto.

When an illustrative embodiment may be implemented differently, a specific process order may be performed differently from the described order. For example, two consecutively described processes may be performed substantially at the same time or performed in an order opposite to the described order.

In the specification, the expression such as “A and/or B” may include A, B, or A and B. The expression such as “at least one of A and B” may include A, B, or A and B.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

In the following embodiment, it will be understood that when a layer, region, or element is referred to as being “connected to” another layer, region, or element, it may be directly connected to the other layer, region, or component or indirectly connected to the other layer, region, or component via intervening layers, regions, or components. For example, in the specification, when a layer, region, or component is referred to as being electrically connected to another layer, region, or component, it may be directly electrically connected to the other layer, region, or component or indirectly electrically connected to the other layer, region, or component via intervening layers, regions, or components.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

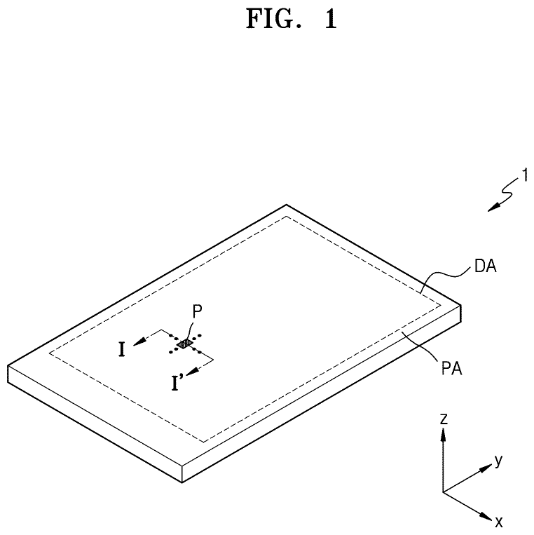

FIG. 1 is a schematic perspective view of an embodiment of a display device 1.

Referring to FIG. 1, the display device 1 may include a display area DA and a peripheral area PA arranged around the display area DA. The peripheral area PA may encompass the display area DA. The display device 1 may provide an image using light emitted from pixels P arranged in the display area DA, and the peripheral area PA may be a non-display area in which no image is displayed.

In the following description, an organic light-emitting display device is described in an embodiment of the display device 1, but the disclosure is not limited thereto. In an embodiment, the display device 1 may include display devices such as an inorganic light-emitting display device (or an inorganic electroluminescent (“EL”) display) or a quantum-dot light-emitting display device. In an embodiment, an emission layer of a display element in the display device 1 may include an organic material, an inorganic material, quantum dots, an organic material and quantum dots, or an inorganic material and quantum dots, for example.

Although FIG. 1 illustrates that the display device 1 has a flat display surface, the disclosure is not limited thereto. In an embodiment, the display device 1 may have a three-dimensional display surface or a curved display surface.

FIG. 1 illustrates the display device 1 that is applicable to a handphone terminal. Although not illustrated, an electronic module, a camera module, a power module, or the like disposed (e.g., mounted) on a mainboard may constitute a handphone terminal by being disposed on a bracket/case or the like with the display device 1. In particular, the display device 1 may be applied to large electronic devices such as a television, a monitor, or the like, as well as small and medium electronic devices such as a tablet computer, a vehicle navigation device, a game console, a smart watch, or the like.

Although FIG. 1 illustrates a case in which the display area DA of the display device 1 is quadrangular, the shape of the display area DA may be circular, oval, or polygonal such as triangular, pentagonal, or the like.

The display device 1 may include the pixels P arranged in the display area DA. Each of the pixels P may include an organic light-emitting diode (“OLED”). Each of the pixels P may emit, e.g., red, green, blue, or white light through the organic light-emitting diode OLED. The pixel P may be understood as a pixel emitting light of any one color of red, green, blue, and white, as described above.

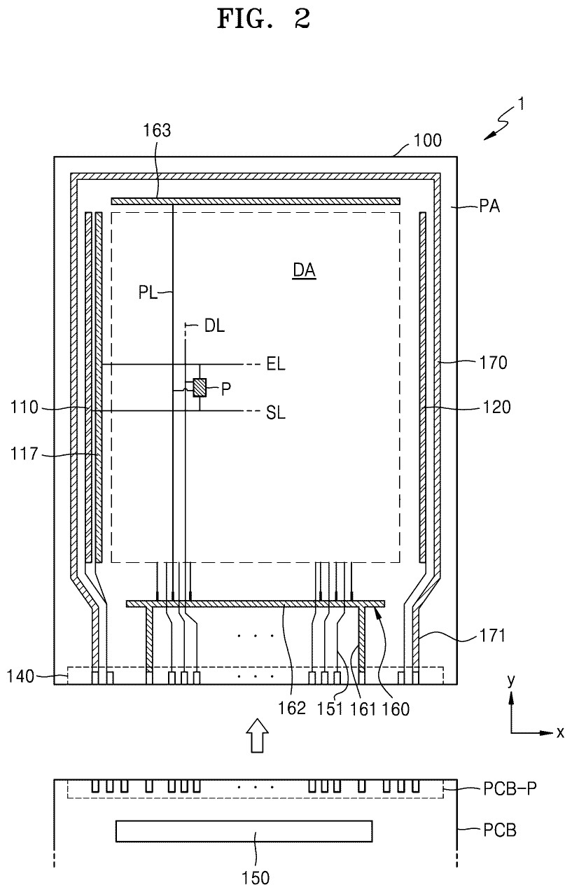

FIG. 2 is a schematic plan view of an embodiment of the display device 1.

Referring to FIG. 2, the display device 1 may include the pixels P arranged in the display area DA. Each pixel P may be electrically connected to outer circuits arranged in the peripheral area PA. A first scan drive circuit 110, an emission drive circuit 117, a second scan drive circuit 120, a terminal 140, a data drive circuit 150, a first power supply wire 160, and a second power supply wire 170 may be disposed in the peripheral area PA.

The first scan drive circuit 110 may provide a scan signal to each pixel P a through a scan line SL. The emission drive circuit 117 may provide an emission control signal to each pixel P through an emission control line EL. The second scan drive circuit 120 may be disposed parallel to the first scan drive circuit 110 with the display area DA therebetween. In an embodiment, some of the pixels P arranged in the display area DA may be electrically connected to the first scan drive circuit 110, and the other pixels P may be electrically connected to the second scan drive circuit 120. In an embodiment, the second scan drive circuit 120 may be omitted.

The emission drive circuit 117 may be disposed in the peripheral area PA apart from the first scan drive circuit 110 in an x direction. Furthermore, the emission drive circuit 117 may be alternately arranged with the first scan drive circuit 110 in a y direction.

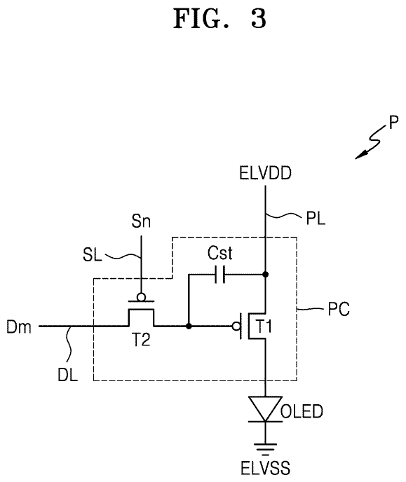

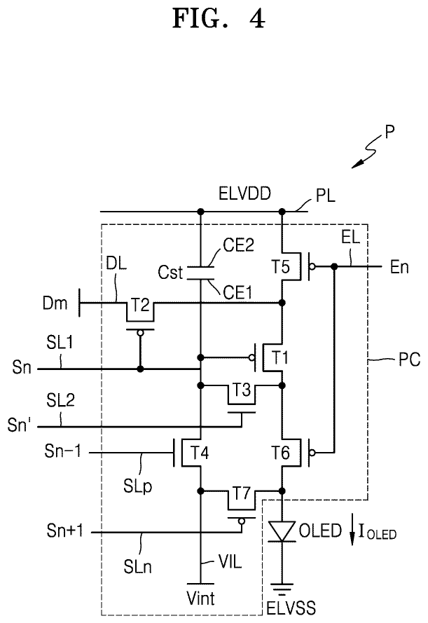

The terminal 140 may be disposed in one side of a substrate 100. The terminal 140 may be electrically connected to a printed circuit board PCB while exposed without being covered by an insulating layer. A terminal PCB-P of the printed circuit board PCB may be electrically connected to the terminal 140 of the display device 1. The printed circuit board PCB may transmit a signal of a controller (not shown) or power to the display device 1. The control signal generated from the controller may be transmitted to each of the first scan drive circuit 110, the emission drive circuit 117, and the second scan drive circuit 120 through the printed circuit board PCB. The controller may provide a first power voltage (ELVDD of FIGS. 3 and 4, also referred to as a driving voltage), and a second power voltage (ELVSS of FIGS. 3 and 4, also referred to as a common voltage) respectively to the first power supply wire 160 and the second power supply wire 170 through a first connection wire 161 and a second connection wire 171. The first power voltage ELVDD may be provided to each pixel P through a driving voltage line PL connected to the first power supply wire 160, and the second power voltage ELVSS may be provided to a counter electrode of each pixel P connected to the second power supply wire 170.

The data drive circuit 150 may be electrically connected to a data line DL. A data signal of the data drive circuit 150 may be provided to each pixel P through a connection wire 151 connected to the terminal 140 and the data line DL connected to the connection wire 151.

Although FIG. 2 illustrates that the data drive circuit 150 is disposed on the printed circuit board PCB, in an embodiment, the data drive circuit 150 may be disposed on the substrate 100. In an embodiment, the data drive circuit 150 may be disposed between the terminal 140 and the first power supply wire 160, for example.

The first power supply wire 160 may include a first sub-wire 162 and a second sub-wire 163 that extend in parallel in the x direction with the display area DA therebetween. The second power supply wire 170 may have a loop shape with one open side and partially surround the display area DA.

FIGS. 3 and 4 are equivalent circuit diagrams of an embodiment of a pixel in a display device.

Referring to FIG. 3, each pixel P may include a pixel circuit PC connected to the scan line SL and the data line DL, and the organic light-emitting diode OLED connected to the pixel circuit PC.

The pixel circuit PC may include a driving thin film transistor (driving TFT; T1), a switching thin film transistor (switching TFT; T2), and a storage capacitor Cst. The switching thin film transistor T2 is connected to the scan line SL and the data line DL, and may transmit a data signal Dm input through the data line DL to the driving thin film transistor T1, in response to a scan signal Sn input through the scan line SL.

The storage capacitor Cst is connected to the switching thin film transistor T2 and the driving voltage line PL, and may store a voltage corresponding to a difference between a voltage received from the switching thin film transistor T2 and a driving voltage ELVDD supplied through the driving voltage line PL.

The driving thin film transistor T1 is connected to the driving voltage line PL and the storage capacitor Cst, and may control a driving current flowing from the driving voltage line PL to the organic light-emitting diode OLED, in response to a value of the voltage stored in the storage capacitor Cst. The organic light-emitting diode OLED may emit light having a predetermined luminance according to the driving current.

Although FIG. 3 illustrates a case in which the pixel circuit PC includes two thin film transistors and one storage capacitor, the disclosure is not limited thereto. In an embodiment, the pixel circuit PC may include three or more thin film transistors and/or two or more storage capacitors, for example. In an embodiment, the pixel circuit PC may include seven thin film transistors and one storage capacitor. In an alternative embodiment, the pixel circuit PC may include seven thin film transistors and two storage capacitors.

Referring to FIG. 4, one the pixel P may include the pixel circuit PC and the organic light-emitting diode OLED electrically connected to the pixel circuit PC.

In an embodiment, the pixel circuit PC may include, as illustrated in FIG. 4, a plurality of thin film transistors T1 to T7 and a storage capacitor Cst. The thin film transistors T1 to T7 and the storage capacitor Cst may be connected to signal lines SL1, SL2, SLp, SLn, EL, and DL, an initialization voltage line VIL, and the driving voltage line PL. In an embodiment, at least any one of the signal lines SL1, SL2, SLp, SLn, EL, and DL, e.g., the initialization voltage line VIL or/and the driving voltage line PL, ma be shared by neighboring pixels P.

The thin film transistors T1 to T7 may include a driving thin film transistor T1, a switching thin film transistor T2, a compensation thin film transistor T3, a first initialization thin film transistor T4, an operation control thin film transistor T5, an emission control thin film transistor T6, and a second initialization thin film transistor T7.

Some of the thin film transistors T1 to T7 may be provided as n-channel MOSFET (“NMOS”) transistors, and the other thin film transistors may be provided as p-channel MOSFET (“PMOS”) transistors.

In an embodiment, as illustrated in FIG. 4, among the thin film transistors T1 to T7, the compensation thin film transistor T3 and the first initialization thin film transistor T4 may be provided as NMOS transistors, and the other thin film transistors may be provided as PMOS transistors, for example.

In an embodiment, among the thin film transistors T1 to T7, the compensation thin film transistor T3, the first initialization thin film transistor T4, and the second initialization thin film transistor T7 may be provided as NMOS transistors, and the other thin film transistors may be provided as PMOS transistors. In an alternative embodiment, while only one of the thin film transistors T1 to T7 may be provided as NMOS transistors, the other thin film transistors may be provided as PMOS transistors. In an alternative embodiment, all of the thin film transistors T1 to T7 may be provided as NMOS transistors.

The signal lines SL1, SL2, SLp, SLn, EL, and DL may include a first scan line SL1 for transmitting a first scan signal Sn, a second scan line SL2 for transmitting a second scan signal Sn′, a previous scan line SLp for transmitting a previous scan signal Sn−1 to the first initialization thin film transistor T4, the emission control line EL for transmitting an emission control signal En to the operation control thin film transistor T5 and the emission control thin film transistor T6, a next scan line SLn for transmitting a next scan signal Sn+1 to the second initialization thin film transistor T7, and the data line DL intersecting the first scan line SL1 and transmitting the data signal Dm.

The driving voltage line PL may transmit the driving voltage ELVDD to the driving thin film transistor T1, and the initialization voltage line VIL may transmit an initialization voltage Vint to initialize the driving thin film transistor T1 and a pixel electrode.

A driving gate electrode of the driving thin film transistor T1 is connected to the storage capacitor Cst, a driving source region of the driving thin film transistor T1 is connected to the driving voltage line PL via the operation control thin film transistor T5, and a driving drain region of the driving thin film transistor T1 is electrically connected to a pixel electrode of the organic light-emitting diode OLED via the emission control thin film transistor T6. The driving thin film transistor T1 may receive the data signal Dm according to a switching operation of the switching thin film transistor T2 and supply a driving current I_{OLED} to the organic light-emitting diode OLED.

A switching gate electrode of the switching thin film transistor T2 is connected to the first scan line SL1, a switching source region of the switching thin film transistor T2 is connected to the data line DL, and a switching drain region of the switching thin film transistor T2 is connected to the driving source region of the driving thin film transistor T1 and the driving voltage line PL via the operation control thin film transistor T5. The switching thin film transistor T2 is turned on in response to the first scan signal Sn received through the first scan line SL1 to perform a switching operation of transmitting the data signal Dm transmitted through the data line DL to the driving source region of the driving thin film transistor T1.

A compensation gate electrode of the compensation thin film transistor T3 may be connected to the second scan line SL2. A compensation drain region of the compensation thin film transistor T3 is connected to the driving drain region of the driving thin film transistor T1 and the pixel electrode of the organic light-emitting diode OLED via the emission control thin film transistor T6. A compensation source region of the compensation thin film transistor T3 is connected to a lower electrode CE1 of the storage capacitor Cst and the driving gate electrode of the driving thin film transistor T1. Furthermore, the compensation source region of the compensation thin film transistor T3 is connected to a first initialization drain region of the first initialization thin film transistor T4.

The compensation thin film transistor T3 is turned on in response to the second scan signal Sn' received through the second scan line SL2 to electrically connect the driving gate electrode and the driving drain region of the driving thin film transistor T1 to each other, thereby allowing the driving thin film transistor T1 to be diode-connected.

A first initialization gate electrode of the first initialization thin film transistor T4 is connected to the previous scan line SLp. A first initialization source region of the first initialization thin film transistor T4 is connected to a second initialization source region of the second initialization thin film transistor T7 and the initialization voltage line VIL. The first initialization drain region of the first initialization thin film transistor T4 is connected to the lower electrode CE1 of the storage capacitor Cst, the compensation source region of the compensation thin film transistor T3, and the driving gate electrode of the driving thin film transistor T1. The first initialization thin film transistor T4 is turned on in response to the previous scan signal Sn−1 received through the previous scan line SLp to transmit the initialization voltage Vint to the driving gate electrode of the driving thin film transistor T1, thereby performing an initialization operation of initializing a voltage of the driving gate electrode of the driving thin film transistor T1.

An operation control gate electrode of the operation control thin film transistor T5 is connected to the emission control line EL, an operation control source region of the operation control thin film transistor T5 is connected to the driving voltage line PL, and an operation control drain region of the operation control thin film transistor T5 is connected to the driving source region of the driving thin film transistor T1 and the switching drain region of the switching thin film transistor T2.

An emission control gate electrode of the emission control thin film transistor T6 is connected to the emission control line EL, an emission control source region of the emission control thin film transistor T6 is connected to the driving drain region of the driving thin film transistor T1 and the compensation drain region of the compensation thin film transistor T3, and an emission control drain region of the emission control thin film transistor T6 is electrically connect to a second initialization drain region of the second initialization thin film transistor T7 and the pixel electrode of the organic light-emitting diode OLED.

The operation control thin film transistor T5 and the emission control thin film transistor T6 are simultaneously turned on in response to the emission control signal En received through the emission control line EL to transmit the driving voltage ELVDD to the organic light-emitting diode OLED, thereby allowing the driving current I_{OLED} to flow in the organic light-emitting diode OLED.

A second initialization gate electrode of the second initialization thin film transistor T7 is connected to the next scan line SLn, the second initialization drain region of the second initialization thin film transistor T7 is connected to the emission control drain region of the emission control thin film transistor T6 and the pixel electrode of the organic light-emitting diode OLED, and the second initialization source region of the second initialization thin film transistor T7 is connected to the first initialization source region of the first initialization thin film transistor T4 and the initialization voltage line VIL. The second initialization thin film transistor T7 is turned on in response to the next scan signal Sn+1 received through the next scan line SLn to initialize the pixel electrode of the organic light-emitting diode OLED.

The second initialization thin film transistor T7 may be connected to the next scan line SLn, as illustrated in FIG. 4. In an embodiment, the second initialization thin film transistor T7 may be connected to the emission control line EL to be driven according to the emission control signal En. The positions of the source regions and the drain regions may be switched each other according to the type (p-type or n-type) of transistors.

The storage capacitor Cst may include the lower electrode CE1 and an upper electrode CE2. The lower electrode CE1 of the storage capacitor Cst is connected to the driving gate electrode of the driving thin film transistor T1, and the upper electrode CE2 of the storage capacitor Cst is connected to the driving voltage line PL. The storage capacitor Cst may store electric charges corresponding to a difference between the voltage of the driving gate electrode of the driving thin film transistor T1 and the driving voltage ELVDD.

A detailed operation of each pixel P in an embodiment is as follows.

During an initialization period, when the previous scan signal Sn−1 is supplied through the previous scan line SLp, the first initialization thin film transistor T4 is turned on in response to the previous scan signal Sn−1, and the driving thin film transistor T1 is initialized by the initialization voltage Vint supplied through the initialization voltage line VIL the driving thin film transistor T1.

During a data programming period, when the first scan signal Sn and the second scan signal Sn′ are respectively supplied through the first scan line SL1 and the second scan line SL2, the switching thin film transistor T2 and the compensation thin film transistor T3 are respectively turned on in response to the first scan signal Sn and the second scan signal Sn'. In this state, the driving thin film transistor T1 is diode-connected by the compensation thin film transistor T3 that is turned on, and is biased in a forward direction.

Then, a compensation voltage (Dm+Vth), where Vth is a negative (−) value, which is equivalent to a voltage obtained by deducting the threshold voltage Vth of the driving thin film transistor T1 from the data signal Dm supplied through the data line DL, is applied to the driving gate electrode of the driving thin film transistor T1.

The driving voltage ELVDD and the compensation voltage (Dm+Vth) are applied to the opposite ends of the storage capacitor Cst, and electric charges corresponding to a voltage difference between the opposite ends are stored in the storage capacitor Cst.

During a light-emitting period, the operation control thin film transistor T5 and the emission control thin film transistor T6 are turned on by the emission control signal En supplied through the emission control line EL. The driving current I_{OLED} according to a difference between the voltage of the driving gate electrode of the driving thin film transistor T1 and the driving voltage ELVDD is generated, and the driving current I_{OLED} is supplied to the organic light-emitting diode OLED through the emission control thin film transistor T6.

In an embodiment, at least one of the thin film transistors T1 to T7 may include a semiconductor layer including an oxide semiconductor, and the other transistors may include a semiconductor layer including a silicon semiconductor.

In detail, the driving thin film transistor T1 directly affecting the brightness of a display device includes a semiconductor layer including or consisting of polycrystalline silicon having relatively high reliability, and a display device with a relatively high resolution may be implemented therethrough.

As an oxide semiconductor has relatively high carrier mobility and a relatively low leakage current, voltage drop is not great even when a driving time is long. In other words, even during relatively low frequency driving, as a color change of an image according to voltage drop is not great, relatively low frequency driving is possible.

As such, as an oxide semiconductor has a merit of a relatively low leakage current, an oxide semiconductor is employed as at least one of the compensation thin film transistor T3, the first initialization thin film transistor T4, and the second initialization thin film transistor T7 connected to the driving gate electrode of the driving thin film transistor T1 so that a leakage current that may flow to the driving gate electrode of the driving thin film transistor T1 may be prevented and simultaneously consumption power may be reduced.

In an embodiment, the driving thin film transistor T1, the switching thin film transistor T2, the operation control thin film transistor T5, the emission control thin film transistor T6, and the second initialization thin film transistor T7 may be provided as a semiconductor layer including a silicon semiconductor, and the compensation thin film transistor T3 and the first initialization thin film transistor T4 may be provided as a semiconductor layer including a oxide semiconductor. However, the disclosure is not limited thereto.

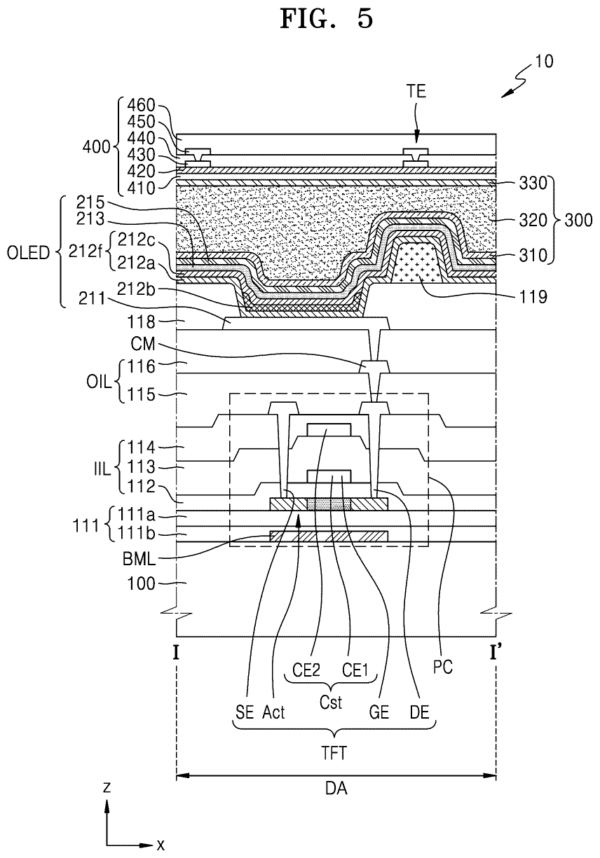

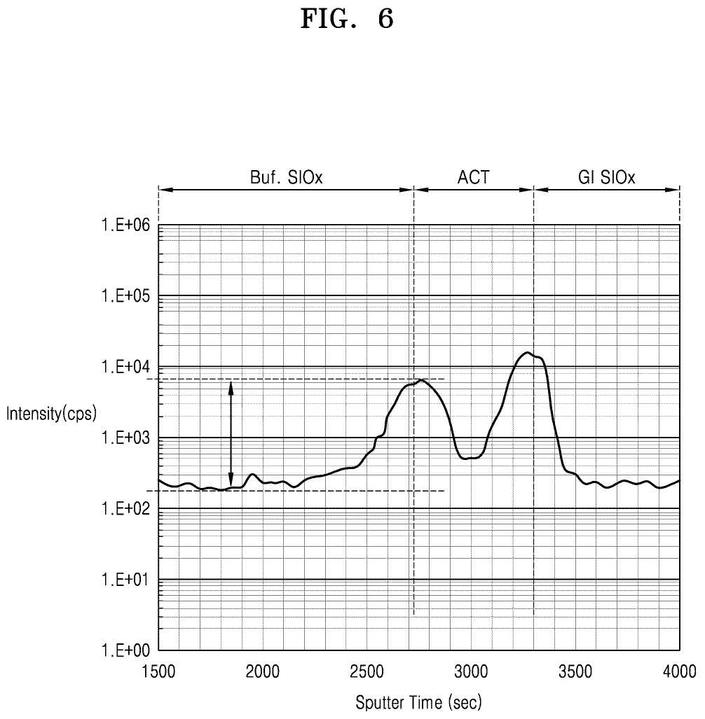

FIG. 5 is a schematic cross-sectional view of a pixel taken along line I-I′ of FIG. 1. FIG. 6 is a graph schematically showing the content (e.g., percent by weight) of fluorine (F) in a first buffer layer, a semiconductor layer, and a first inorganic insulating layer.

Referring to FIG. 5, a display panel 10 of the display device 1 may include the substrate 100, an inorganic insulating layer IIL, an organic insulating layer OIL, the pixel circuit PC, a connection electrode CM, the organic light-emitting diode OLED, a pixel defining layer 118, a spacer 119, and an encapsulation layer 300. In other words, the substrate 100, the inorganic insulating layer IIL, the organic insulating layer OIL, the pixel circuit PC, the connection electrode CM, the organic light-emitting diode OLED, the pixel defining layer 118, the spacer 119, and the encapsulation layer 300 may be disposed in the display area DA of the display panel 10.

The substrate 100 may include or consist of various materials, such as a glass material, a metal material, a plastic material, or the like. When the substrate 100 is a flexible substrate, the substrate 100 may include, e.g., polymer resin, such as polyethersulfone (“PES”), polyacrylate (“PAR”), polyetherimide (“PEI”), polyethylene naphthalate (“PEN”), polyethylene terephthalate (“PET”), polyphenylene sulfide (“PPS”), polyarylate, polyimide (“PI”), polycarbonate (“PC”), or cellulose acetate propionate (“CAP”).

As an optional embodiment, the substrate 100 may have a structure including two plastic substrates next to each other and an inorganic layer between the two plastic substrates. The two plastic substrates may include the polymer resin described above, and may have the same or different thicknesses. In an embodiment, the two plastic substrates may each include polyimide and may have a thickness of 3 micrometers (μm) to 20 μm, for example. The inorganic layer, as a barrier layer for preventing infiltration of external foreign materials, may be a single layer or multilayer including an inorganic material, such as silicon nitride (SiNₓ) and/or silicon oxide (SiOₓ). The inorganic layer may have a thickness of about 6000 angstroms (Å), but the disclosure is not limited thereto.

A bottom metal layer (also referred to as a metal layer) BML may be disposed on the substrate 100. The bottom metal layer BML may include aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The bottom metal layer BML may be a single layer or multilayer of the materials described above.

A buffer layer 111 may be disposed on the substrate 100. The buffer layer 111 may include a first buffer layer 111a and a second buffer layer 111b. The second buffer layer 111b may be disposed below the first buffer layer 111a. The first buffer layer 111a may include SiOₓ, and the second buffer layer 111b may include SiNₓ.

The inorganic insulating layer IIL may be disposed on the buffer layer 111. The inorganic insulating layer IIL may include a first inorganic insulating layer 112, a second inorganic insulating layer 113, and a third inorganic insulating layer 114.

The pixel circuit PC may be disposed in the display area DA. The pixel circuit PC may include a thin film transistor TFT and the storage capacitor Cst. The thin film transistor TFT may include a semiconductor layer Act, a gate electrode GE, a source electrode SE, and a drain electrode DE.

The semiconductor layer Act may be disposed on the buffer layer 111. The semiconductor layer Act may include polysilicon. In an alternative embodiment, the semiconductor layer Act may include amorphous silicon. The semiconductor layer Act may include a channel region, and a drain region and a source region arranged on opposite sides of the channel region.

The gate electrode GE may be disposed on the semiconductor layer Act. The gate electrode GE may overlap the channel region. The gate electrode GE may include a relatively low resistance metal material. The gate electrode GE may include a conductive material including Mo, Al, Cu, titanium (Ti), or the like, and may be formed in a multilayer or single layer including the materials described above.

The first inorganic insulating layer 112 may be disposed between the semiconductor layer Act and the gate electrode GE. The first inorganic insulating layer 112 may include an inorganic insulating material, such as silicon oxide (SiO₂), SiNₓ, silicon oxynitride (SiON), aluminum oxide (Al₂O₃), titanium oxide (TiO₂), tantalum oxide (Ta₂O₅), hafnium oxide (HfO₂), ZnO, or the like.

The thin film transistor TFT illustrated in FIG. 5 may be the driving thin film transistor T1 of the pixel circuit PC illustrated in FIG. 4.

When white-color stress is applied to the driving thin film transistor TFT, a negative bias is applied to the driving thin film transistor TFT, the driving range of the driving thin film transistor TFT may be reduced, and as the amount of a current flowing in the driving thin film transistor TFT at the same voltage decreases, the luminance of the display device 1 may be reduced.

In an embodiment, the content of a compound including or consisting of a SiO—H bond in the first inorganic insulating layer 112 may be 0.9% or less based on the total weight of the first inorganic insulating layer 112. In this case, the concentration of hydrogen (H) in the first inorganic insulating layer 112 may be 7.55×10²⁰ atoms per cubic centimeter (atom/cm³) or less. The content of the compound including or consisting of the SiO—H bond in the first inorganic insulating layer 112, when the content is 0.9% or less based on the total weight of the first inorganic insulating layer 112, may prevent acting as a trap site for electrons as the SiO—H bond is broken at an interface between the first inorganic insulating layer 112 and the semiconductor layer Act. When the trap site for electrons is reduced at the interface between the first inorganic insulating layer 112 and the semiconductor layer Act, the driving range of the driving thin film transistor TFT increases, and the amount of a current flowing when the same voltage is applied to the driving thin film transistor TFT may be increased so that the reduction of the luminance of the display device 1 may be prevented.

In an embodiment, the content of a compound including or consisting of a nitrogen-hydrogen (N—H) bond in the first buffer layer 111a may be 0.1% or less based on the total weight of the first buffer layer 111a. In this case, the concentration of H in the first buffer layer 111a may be 8.5×10²⁰ atom/cm³ or less. The content of the compound including or consisting of the N—H bond in the first buffer layer 111a, when the content is 0.1% or less based on the total weight of the first buffer layer 111a, may prevent acting as a trap site for electrons as the N—H bond is broken at an interface between the first buffer layer 111a and the semiconductor layer Act. When the trap site for electrons at the interface between the first buffer layer 111a and the semiconductor layer Act is reduced, the driving range of the driving thin film transistor TFT increases, and the amount of a current flowing when the same voltage is applied to the driving thin film transistor TFT may be increased so that the reduction of the luminance of the display device 1 may be prevented.

When the semiconductor layer Act is disposed on the first buffer layer 111a including SiOₓ, a threshold voltage of the driving thin film transistor TFT may have a negative shift. By injecting fluorine (F) into the first buffer layer 111a and the semiconductor layer Act, the content of fluorine at the interface between the first buffer layer 111a and the semiconductor layer Act may be increased, a phenomenon in which the threshold voltage of the driving thin film transistor TFT has a negative shift may be prevented.

Referring to FIG. 6, the intensity indicated on a y-axis in the graph may be the content of fluorine. In an embodiment, the content of fluorine in the interface between the first buffer layer 111a and the semiconductor layer Act may be six times or more of the content of fluorine in a lower portion of the first buffer layer 111a. When the content of fluorine in the interface between the first buffer layer 111a and the semiconductor layer Act is six times or more of a minimum value of the content of fluorine in the lower portion of the first buffer layer 111a, the phenomenon in which the threshold voltage of the driving thin film transistor TFT has a negative shift may be prevented. Furthermore, as fluorine binds to dangling bonds existing in the interface between the first buffer layer 111a and the semiconductor layer Act, the amount of dangling bonds that may act as the trap site for electrons may decrease, and the amount of a current flowing when the same voltage is applied to the driving thin film transistor TFT increases so that the reduction of the luminance of the display device 1 may be prevented.

The second inorganic insulating layer 113 may be disposed on the gate electrode GE. The second inorganic insulating layer 113 may be provided to cover the gate electrode GE. The second inorganic insulating layer 113 may include an inorganic insulating material, such as SiO₂, SiNₓ, SiON, Al₂O₃, TiO₂, Ta₂O₅, HfO₂, ZnO, or the like.

The upper electrode CE2 of the storage capacitor Cst may be disposed on the second inorganic insulating layer 113. The upper electrode CE2 may overlap the gate electrode GE disposed thereunder. In this state, the gate electrode GE and the upper electrode CE2 overlapping each other with the second inorganic insulating layer 113 therebetween may form the storage capacitor Cst. In other words, the gate electrode GE may function as the lower electrode CE1 of the storage capacitor Cst.

As such, the storage capacitor Cst and the thin film transistor TFT may be formed to overlap each other. However, the disclosure is not limited thereto. In an embodiment, the storage capacitor Cst may be formed not to overlap the thin film transistor TFT, for example. In other words, the lower electrode CE1 of the storage capacitor Cst may be provided to be spaced apart from the gate electrode GE of the thin film transistor TFT, as a separate component from the gate electrode GE of the thin film transistor TFT.

The upper electrode CE2 may include Al, Pt, Pd, Ag, Mg, Au, Ni, Nd, Ir, Cr, Ca, Mo, Ti, W, and/or Cu, and may be a single layer or multilayer of the materials described above.

The third inorganic insulating layer 114 may be disposed on the upper electrode CE2. The third inorganic insulating layer 114 may cover the upper electrode CE2. The third inorganic insulating layer 114 may include SiO₂, SiNₓ, SiON, Al₂O₃, TiO₂, Ta₂O₅, HfO₂, ZnO, or the like. The third inorganic insulating layer 114 may be a single layer or multilayer including the inorganic insulating materials described above.

The drain electrode DE and the source electrode SE may each be disposed on the third inorganic insulating layer 114. The drain electrode DE and the source electrode SE may each be connected to the semiconductor layer Act through contact holes in the first inorganic insulating layer 112, the second inorganic insulating layer 113, and the third inorganic insulating layer 114. The drain electrode DE and the source electrode SE may include a material with goof conductivity. The drain electrode DE and the source electrode SE may each include a conductive material including Mo, Al, Cu, Ti, or the like, and may be formed in a multilayer or single layer including the materials described above. In an embodiment, the drain electrode DE and the source electrode SE may each have a multilayer structure of Ti/Al/Ti, for example.

The organic insulating layer OIL may be disposed on the inorganic insulating layer IIL. The organic insulating layer OIL may include a first organic insulating layer 115 and a second organic insulating layer 116. Although FIG. 6 illustrates that the organic insulating layer OIL includes two organic insulating layers, the disclosure is not limited thereto. The organic insulating layer OIL may include three or four organic insulating layers.

The first organic insulating layer 115 may cover the drain electrode DE and the source electrode SE. The first organic insulating layer 115 may include an organic insulating material, such as a general purpose polymer such as polymethylmethacrylate (“PMMA”) or polystyrene (“PS”), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and blends thereof.

The connection electrode CM may be disposed on the first organic insulating layer 115. In this state, the connection electrode CM may be connected to the drain electrode DE or the source electrode SE through a contact hole in the first organic insulating layer 115. The connection electrode CM may include a material with goof conductivity. The connection electrode CM may include a conductive material including Mo, Al, Cu, Ti, or the like, and may be formed in a multilayer or single layer including the materials described above. In an embodiment, the connection electrode CM may have a multilayer structure of Ti/Al/Ti, for example.

The second organic insulating layer 116 may be disposed on the connection electrode CM. The second organic insulating layer 116 may cover the connection electrode CM. The second organic insulating layer 116 may include the same material as or a different material from the first organic insulating layer 115.

A light-emitting diode may be disposed on the second organic insulating layer 116. In an embodiment, the organic light-emitting diode OLED may be disposed on the second organic insulating layer 116, for example. In an alternative embodiment, although not illustrated, an inorganic light-emitting diode or the like may be disposed on the second organic insulating layer 116.

The organic light-emitting diode OLED may emit red, green, or blue light or red, green, blue, or white light. The organic light-emitting diode OLED may include a sub-pixel electrode 211, an emission layer 212b, a function layer 212f, a counter electrode 213, and a capping layer 215.

The sub-pixel electrode 211 may be disposed on the second organic insulating layer 116. The sub-pixel electrode 211 may be electrically connected to the connection electrode CM through a contact hole defined in the second organic insulating layer 116. The sub-pixel electrode 211 may include conductive oxide, such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In an embodiment, the sub-pixel electrode 211 may include a reflective film including Ag, Mg, Al, Pt, Pd, Au, Ni, Nd, Ir, Cr, or compounds thereof. In an embodiment, the sub-pixel electrode 211 may further include a film including or consisting of ITO, IZO, ZnO, or In₂O₃ above/below the reflective film described above. In an embodiment, the sub-pixel electrode 211 may have a multilayer structure of ITO/Ag/ITO, for example.

A pixel defining layer 118, in which an opening to expose at least a portion of the sub-pixel electrode 211 is defined, may be disposed on the sub-pixel electrode 211. An emission area of light emitted from the organic light-emitting diode OLED may be defined by the opening defined in the pixel defining layer 118. In an embodiment, the width of the opening may correspond to the width of the emission area, for example.

The pixel defining layer 118 may include an organic insulating material. In an alternative embodiment, the pixel defining layer 118 may include an inorganic insulating material, such as silicon nitride, silicon oxynitride, or silicon oxide. In an alternative embodiment, the pixel defining layer 118 may include an organic insulating material and an inorganic insulating material. In an embodiment, the pixel defining layer 118 may include a light-blocking material. The light-blocking material may include resin or paste including carbon black, carbon nanotube, and black dye, metal particles, e.g., nickel, aluminum, molybdenum, and alloys thereof, metal oxide particles (e.g., chromium oxide) or metal nitride particles (e.g., chromium nitride), or the like. When the pixel defining layer 118 includes a light-blocking material, the reflection of external light due to metal structures disposed under the pixel defining layer 118 may be reduced.

The spacer 119 may be disposed on the pixel defining layer 118. The spacer 119 may include an organic insulating material such as polyimide. In an alternative embodiment, the spacer 119 may include an inorganic insulating material, such as SiNₓ or SiO₂, or an organic insulating material and an inorganic insulating material.

In an embodiment, the spacer 119 may include the same material as that of the material of the pixel defining layer 118. In this case, the pixel defining layer 118 and the spacer 119 may be formed together in a mask process using a half-tone mask or the like. In an alternative embodiment, the spacer 119 and the pixel defining layer 118 may include a different material from each other.

The emission layer 212b may be disposed in the opening of the pixel defining layer 118. The emission layer 212b may include a polymeric or relatively low molecular weight organic material that emits light of a predetermined color.

The function layer 212f may include a first function layer 212a and a second function layer 212c. The first function layer 212a may be disposed between the sub-pixel electrode 211 and the emission layer 212b, and the second function layer 212c may be disposed between the emission layer 212b and the counter electrode 213. However, at least one of the first function layer 212a or the second function layer 212c may be omitted. In the following description, a case in which each of the first function layer 212a and the second function layer 212c is arranged is mainly described in detail.

The first function layer 212a may include a hole transport layer (“HTL”) and/or a hole injection layer (“HIL”). The second function layer 212c may include an electron transport layer (“ETL”) and/or an electron injection layer (“EIL”). The first function layer 212a and/or the second function layer 212c may each be a common layer formed to cover an entirety of the substrate 100, like the counter electrode 213 to be described below.

The counter electrode 213 may be disposed on the function layer 212f. The counter electrode 213 may include a conductive material having a relatively low work function. In an embodiment, the counter electrode 213 may include a (semi-) transparent layer including Ag, Mg, Al, Pt, Pd, Au, Ni, Nd, Ir, Cr, Li, Ca, alloys thereof, or the like, for example. In an alternative embodiment, the counter electrode 213 may further include a layer including ITO, IZO, ZnO, or In₂O₃ on the (semi-) transparent layer including the materials described above.

In an embodiment, the capping layer 215 may be disposed on the counter electrode 213. The capping layer 215 may include LiF, an inorganic material, or/and an organic material.

The encapsulation layer 300 may be disposed on the organic light-emitting diode OLED. The encapsulation layer 300 may cover the organic light-emitting diode OLED. The encapsulation layer 300 may be disposed on the counter electrode 213 and/or the capping layer 215. In an embodiment, the encapsulation layer 300 may include at least one inorganic film layer and at least one organic film layer. FIG. 5 illustrates that the encapsulation layer 300 includes a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may each include one or more inorganic materials of aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may each be a single layer or multilayer including the materials described above. The organic encapsulation layer 320 may include a polymer-based material. The polymer-based material may include acrylic resin, epoxy-based resin, polyimide and polyethylene, or the like. In an embodiment, the organic encapsulation layer 320 may include acrylate.

A touch sensor layer 400 may be disposed on the encapsulation layer 300. The touch sensor layer 400 may include a first touch insulating layer 410, a second touch insulating layer 420, a first conductive layer 430, a third touch insulating layer 440, a second conductive layer 450, and a planarization layer 460.

In an embodiment, the first touch insulating layer 410 may be disposed on the second inorganic encapsulation layer 330, and the second touch insulating layer 420 may be disposed on the first touch insulating layer 410. In an embodiment, the first touch insulating layer 410 and the second touch insulating layer 420 may each include an inorganic insulating material and/or an organic insulating material. In an embodiment, the first touch insulating layer 410 and the second touch insulating layer 420 may each include an inorganic insulating material, such as silicon oxide, silicon nitride, and/or silicon oxynitride, for example.

In an embodiment, at least one of the first touch insulating layer 410 and the second touch insulating layer 420 may be omitted. In an embodiment, the first touch insulating layer 410 may be omitted, for example. In this case, the second touch insulating layer 420 may be disposed on the second inorganic encapsulation layer 330, and the first conductive layer 430 may be disposed on the second touch insulating layer 420.

The first conductive layer 430 may be disposed on the second touch insulating layer 420, and the third touch insulating layer 440 may be disposed on the first conductive layer 430. In an embodiment, the third touch insulating layer 440 may include an inorganic insulating material and/or an organic insulating material. In an embodiment, the third touch insulating layer 440 may include an inorganic insulating material, such as silicon oxide, silicon nitride, and/or silicon oxynitride, for example.

The second conductive layer 450 may be disposed on the third touch insulating layer 440. A touch electrode TE of the touch sensor layer 400 may have a structure in which the first conductive layer 430 and the second conductive layer 450 are connected to each other. In an alternative embodiment, the touch electrode TE may be formed on any one layer of the first conductive layer 430 and the second conductive layer 450, and may include a metal line on the corresponding conductive layer. The first conductive layer 430 and the second conductive layer 450 may each include at least one of Al, Cu, Ti, Mo, and ITO, and may include a single layer or multilayer including the materials described above. In an embodiment, the first conductive layer 430 and the second conductive layer 450 may each have a three-layer structure of a titanium layer/an aluminum layer/a titanium layer, for example.

In an embodiment, the planarization layer 460 may cover the second conductive layer 450. The planarization layer 460 may include an organic insulating material.

In an embodiment, the concentration of H in the first inorganic insulating layer 112 disposed above the driving thin film transistor TFT including a silicon semiconductor material is 7.55×10¹⁹ atom/cm³ or less, the content of a compound including or consisting of an N—H bond in the first buffer layer 111a disposed under the driving thin film transistor TFT is 0.1% or less based on the total weight of the first buffer layer 111a, and the concentration of H in the first buffer layer 111a is 8.5×10²⁰ atom/cm³ or less. Thus, the trap site for electrons may be reduced at the upper and lower interfaces of the semiconductor layer Act of the driving thin film transistor TFT, and thus, the amount of a current flowing when the same voltage is applied to the driving thin film transistor TFT may be increased, and during white-color stress, a negative bias is applied to the driving thin film transistor TFT so that the reduction of the luminance of the display device 1 may be prevented.

As described above, in an embodiment, a display device with improved reliability and quality may be implemented. The scope of the disclosure is not limited by the above effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display device comprising:
a substrate;
a first buffer layer disposed on the substrate;
a thin film transistor comprising:
a semiconductor layer disposed on the first buffer layer; and
a gate electrode insulated from the semiconductor layer; and
a first inorganic insulating layer disposed between the semiconductor layer and the gate electrode,
wherein a concentration of hydrogen (H) in the first inorganic insulating layer is about 7.55×10²⁰ atoms per cubic centimeter or less, and
a content of a compound including a nitrogen-hydrogen (N—H) bond in the first buffer layer is about 0.1% or less based on a total weight of the first buffer layer.

2. The display device of claim 1, wherein the concentration of hydrogen (H) in the first buffer layer is about 8.5×10²⁰ atoms per cubic centimeter or less.

3. The display device of claim 1, wherein the first buffer layer comprises silicon oxide (SiOₓ).

4. The display device of claim 1, further comprising a second buffer layer disposed below the first buffer layer.

5. The display device of claim 4, wherein the second buffer layer comprises silicon nitride (SiNₓ).

6. The display device of claim 1, wherein the first inorganic insulating layer comprises silicon oxide (SiOₓ).

7. The display device of claim 1, wherein a content of fluorine (F) in an interface between the buffer layer and the semiconductor layer is six times or more of a minimum value of a content of fluorine (F) in a lower portion of the buffer layer.

8. The display device of claim 1, wherein the semiconductor layer comprises a silicon semiconductor material.

9. The display device of claim 1, further comprising a metal layer disposed on the substrate.

10. The display device of claim 1, wherein the thin film transistor comprises a driving thin film transistor.

11. The display device of claim 1, wherein the substrate comprises a glass material.

12. The display device of claim 1, wherein the substrate comprises an inorganic layer disposed between plastic substrates next to each other.

13. The display device of claim 12, wherein the plastic substrates each comprise polyimide.

14. The display device of claim 12, wherein the inorganic layer comprises silicon oxide (SiOₓ).

15. The display device of claim 1, further comprising an organic insulating layer disposed on the first inorganic insulating layer.

16. The display device of claim 15, wherein an organic light-emitting diode disposed on the organic insulating layer.

17. The display device of claim 16, wherein the organic light-emitting diode comprises a pixel electrode, an emission layer, and a counter electrode.

18. The display device of claim 17, further comprising an encapsulation layer disposed on the organic light-emitting diode.

19. The display device of claim 18, wherein the encapsulation layer comprises a first inorganic encapsulation layer, an organic encapsulation layer, and a second inorganic encapsulation layer.

20. The display device of claim 1, further comprising a storage capacitor disposed on the thin film transistor.
